(19) United States
(12) Patent Application Publication
(10) Pub. No.: US 2023/0120462 A1
(43) Pub. Date: Apr. 20, 2023

(54) POWER AMPLIFIER SYSTEM WITH INCREASED OUTPUT POWER FOR ENVELOPE TRACKING APPLICATIONS

(71) Applicant: Skyworks Solutions, Inc., Irvine, CA (US)

(72) Inventors: Florinel G. Balteanu, Irvine, CA (US); John Tzung-Yin Lee, Costa Mesa, CA (US); Aniruddha B. Joshi, Irvine, CA (US)

(21) Appl. No.: 17/964,297

(22) Filed: Oct. 12, 2022

Related U.S. Application Data
(60) Provisional application No. 63/256,413, filed on Oct. 15, 2021.

(51) Int. Cl. H03F 3/24; H03F 1/02; H03F 3/195

(52) U.S. Cl. CPC H03F 3/245; H03F 1/0227; H03F 3/195; H03F 2200/102; H03F 2200/451

(57) ABSTRACT

A power amplifier system comprises an envelope tracker configured to generate a supply voltage that changes in relation to an envelope of a radio frequency signal, a power amplifier configured to amplify the radio frequency signal, and an adaptation circuit configured to adapt the supply voltage to provide operating power to the power amplifier. The adaptation circuit includes at least one Gallium Nitride field-effect-transistor configured to generate the operating power in response to an increased swing of the supply voltage and at least one linearizing circuit configured to linearize an operation of the Gallium Nitride field-effect-transistor.

### INCORPORATION BY REFERENCE TO ANY PRIORITY APPLICATIONS

Any and all applications, if any, for which a foreign or domestic priority claim is identified in the Application Data Sheet of the present application, including U.S. Provisional Patent Application No. 63/256,413, filed Oct. 15, 2021, titled “POWER AMPLIFIER SYSTEM WITH INCREASED OUTPUT POWER FOR ENVELOPE TRACKING APPLICATIONS,” are hereby incorporated by reference under 37 CFR 1.57 in their entirety.

### BACKGROUND

### Field

Embodiments of the invention relate to electronic systems, and in particular, to power amplifiers for use in radio frequency (RF) electronics.

### Description of the Related Technology

Power amplifiers are used in radio frequency (RF) communication systems to amplify RF signals for transmission via antennas. It is important to manage the power of RF signal transmissions to prolong battery life and/or provide a suitable transmit power level.

Examples of RF communication systems with one or more power amplifiers include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. An RF signal can have a frequency in the range of about 30 kHz to 300 GHz, such as in the range of about 410 MHz to about 7.125 GHz for certain communications standards.

### BRIEF DESCRIPTION OF THE DRAWINGS

FIG. 1 is a schematic diagram of one example of a communication network.

FIG. 2A is a schematic diagram of one example of a downlink channel using multi-input and multi-output (MIMO) communications.

FIG. 2B is schematic diagram of one example of an uplink channel using MIMO communications.

FIG. 2C is schematic diagram of another example of an uplink channel using MIMO communications.

FIG. 3 is a schematic diagram of one embodiment of a mobile device.

FIG. 4 is a schematic diagram of one embodiment of a transmit system for transmitting radio frequency (RF) signals from a mobile device.

FIG. 5 is an example of structure of two channel receiver front end.

FIGS. 6A and 6B is an example of graphs describing the data rate and SNR required.

FIG. 7 is an example of structure for power amplifier system according to an embodiment.

FIG. 8 is an example of structure for GaN FET according to an embodiment.

FIG. 9 is an example of structure for power amplifier system 700′ including a multi-level supply (MLS) modulator 730 according to an embodiment.

FIG. 10 is an example of structure for power amplifier system 700″ according to an embodiment.

FIG. 11 is an example representing a power added efficiency (PAE) depending on output power for the power amplifier system according to an embodiment.

FIG. 12 is an example of structure of communication device for describing synchronization scheme.

FIG. 13A is a schematic diagram of an envelope tracking system according to one embodiment.

FIG. 13B is a schematic diagram of an envelope tracking system according to another embodiment.

FIG. 14 is a schematic diagram of an envelope tracking system according to another embodiment.

FIG. 15A is a schematic diagram of one embodiment of a packaged module.

FIG. 15B is a schematic diagram of a cross-section of the packaged module of FIG. 15A taken along the lines 15A-15B.

FIG. 16 is a schematic diagram of one embodiment of a phone board.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

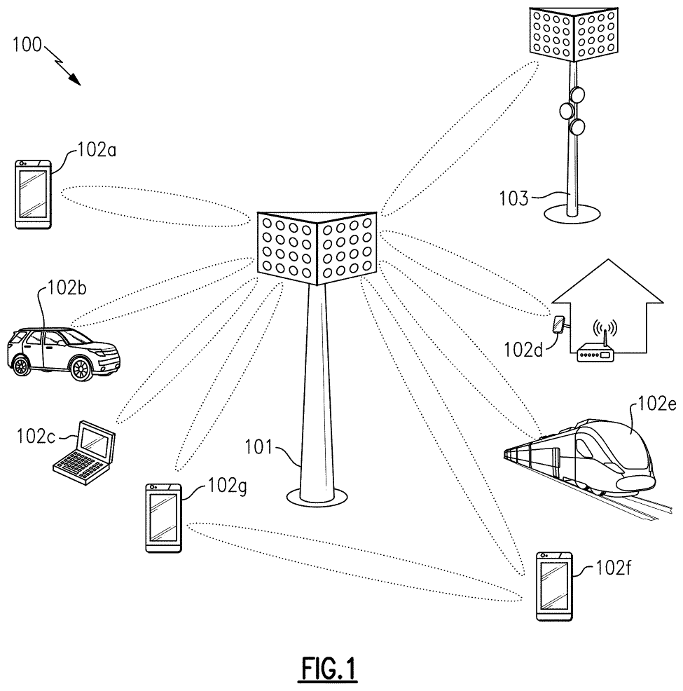

FIG. 1 is a schematic diagram of one example of a communication network 100. The communication network 100 includes a macro cell base station 101, a small cell base station 103, and various examples of user equipment (UE), including a first mobile device 102 a, a wireless-connected car 102 b, a laptop 102 c, a stationary wireless device 102 d, a wireless-connected train 102 e, a second mobile device 102 f, and a third mobile device 102 g.

Although specific examples of base stations and user equipment are illustrated in FIG. 1, a communication network can include base stations and user equipment of a wide variety of types and/or numbers.

For instance, in the example shown, the communication network 100 includes the macro cell base station 101 and the small cell base station 103. The small cell base station 103 can operate with relatively lower power, shorter range, and/or with fewer concurrent users relative to the macro cell base station 101. The small cell base station 3 can also be referred to as a femtocell, a picocell, or a microcell. Although the communication network 100 is illustrated as including two base stations, the communication network 100 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 100 of FIG. 1 supports communications using a variety of cellular technologies, including, for example, 4G LTE and 5G NR. In certain implementations, the communication network 10 is further adapted to provide a wireless local area network (WLAN), such as WiFi. Although various examples of communication technologies have been provided, the communication network 100 can be adapted to support a wide variety of communication technologies.

Various communication links of the communication network 100 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 100 can be implemented to support self-fronthaul and/or self-backhaul (for instance, as between mobile device 102 g and mobile device 102 f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 48 GHz.

Different users of the communication network 100 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 100 of FIG. 1 can be used to support a wide variety of advanced communication features, including, but not limited to, eMBB, uRLLC, and/or mMTC.

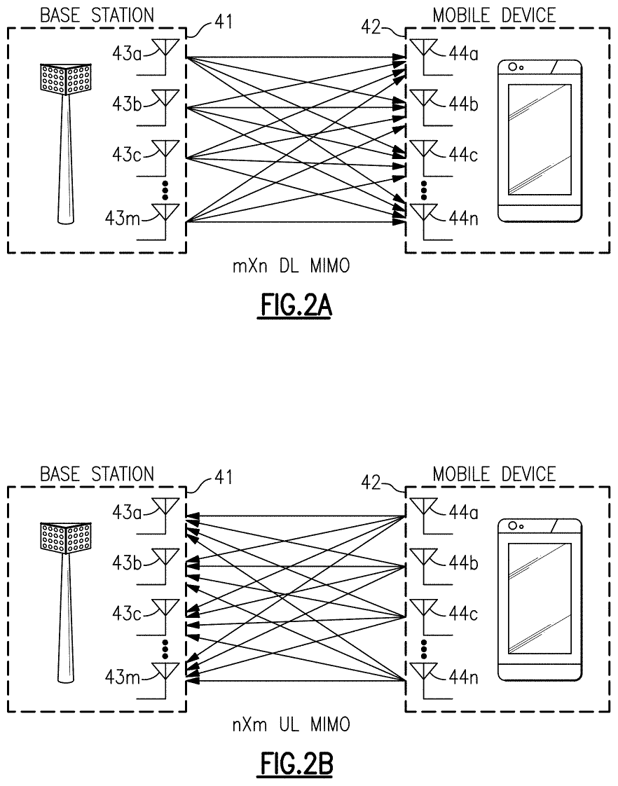

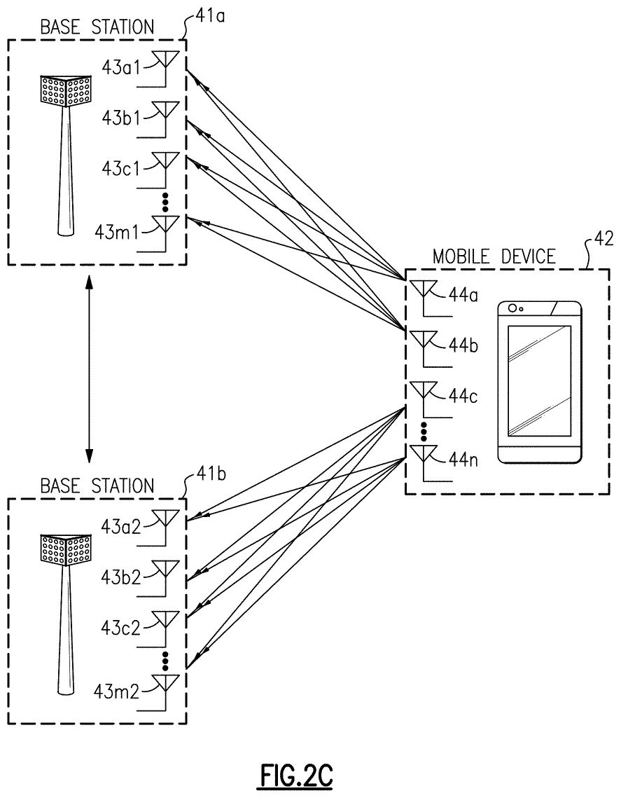

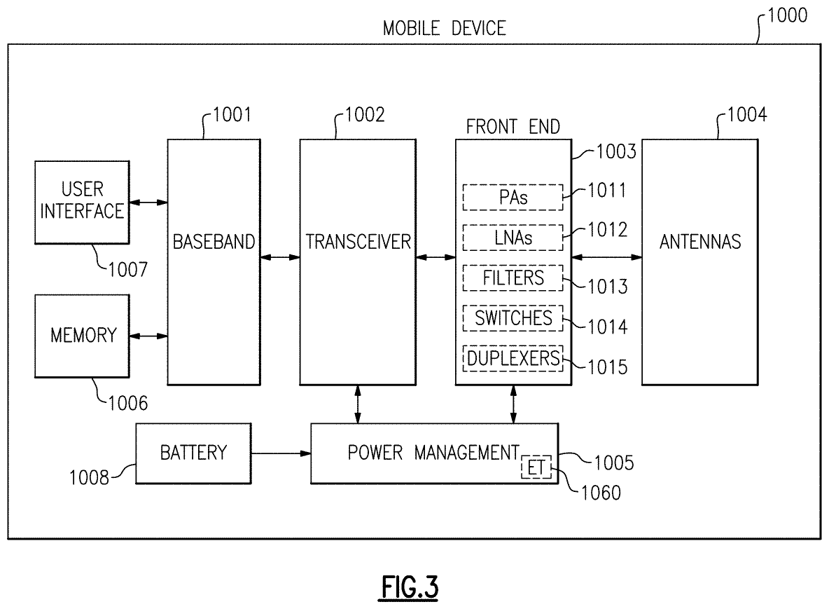

FIG. 2A is a schematic diagram of one example of a downlink channel using multi-input and multi-output (MIMO) communications. FIG. 2B is schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

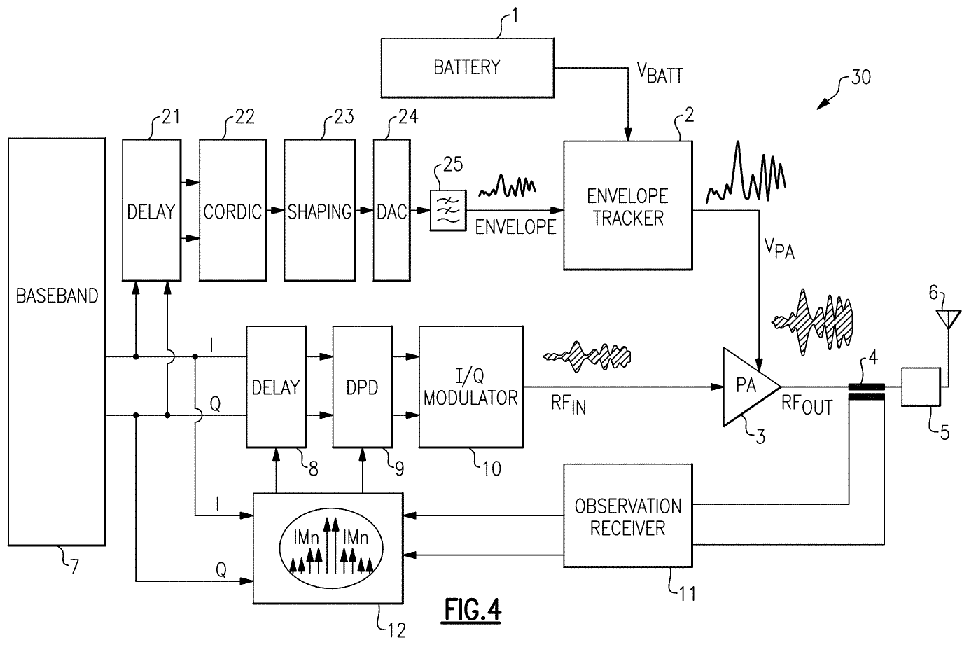

In the example shown in FIG. 2A, downlink MIMO communications are provided by transmitting using M antennas 43 a, 43 b, 43 c, . . . 43 m of the base station 41 and receiving using N antennas 44 a, 44 b, 44 c, . . . 44 n of the mobile device 42. Accordingly, FIG. 4A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 2B, uplink MIMO communications are provided by transmitting using N antennas 44 a, 44 b, 44 c, . . . 44 n of the mobile device 42 and receiving using M antennas 43 a, 43 b, 43 c, . . . 43 m of the base station 41. Accordingly, FIG. 4B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

FIG. 2C is schematic diagram of another example of an uplink channel using MIMO communications. In the example shown in FIG. 2C, uplink MIMO communications are provided by transmitting using N antennas 44 a, 44 b, 44 c, . . . 44 n of the mobile device 42. Additional a first portion of the uplink transmissions are received using M antennas 43 a 1, 43 b 1, 43 c 1, . . . 43 m 1 of a first base station 41 a, while a second portion of the uplink transmissions are received using M antennas 43 a 2, 43 b 2, 43 c 2, . . . 43 m 2 of a second base station 41 b. Additionally, the first base station 41 a and the second base station 41 b communication with one another over wired, optical, and/or wireless links.

The MIMO scenario of FIG. 4C illustrates an example in which multiple base stations cooperate to facilitate MIMO communications.

FIG. 3 is a schematic diagram of one example of a mobile device 1000. The mobile device 1000 includes a baseband system 1001, a transceiver 1002, a front end system 1003, antennas 1004, a power management system 1005, a memory 1006, a user interface 1007, and a battery 1008.

The mobile device 1000 can be used communicate using a wide variety of communications technologies, including, but not limited to, 2G, 3G, 4G (including LTE, LTE-Advanced, and LTE-Advanced Pro), 5G, WLAN (for instance, Wi-Fi), WPAN (for instance, Bluetooth and ZigBee), WMAN (for instance, WiMax), and/or GPS technologies.

The transceiver 1002 generates RF signals for transmission and processes incoming RF signals received from the antennas 1004. It will be understood that various functionalities associated with the transmission and receiving of RF signals can be achieved by one or more components that are collectively represented in FIG. 1 as the transceiver 1002. In one example, separate components (for instance, separate circuits or dies) can be provided for handling certain types of RF signals.

The front end system 1003 aids is conditioning signals transmitted to and/or received from the antennas 1004. In the illustrated embodiment, the front end system 1003 includes power amplifiers (PAs) 1011, low noise amplifiers (LNAs) 1012, filters 1013, switches 1014, and duplexers 1015. However, other implementations are possible.

For example, the front end system 1003 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 1000 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band and/or in different bands.

The antennas 1004 can include antennas used for a wide variety of types of communications. For example, the antennas 1004 can include antennas associated transmitting and/or receiving signals associated with a wide variety of frequencies and communications standards.

In certain implementations, the antennas 1004 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 1000 can operate with beamforming in certain implementations. For example, the front end system 1003 can include phase shifters having variable phase controlled by the transceiver 1002. Additionally, the phase shifters are controlled to provide beam formation and directivity for transmission and/or reception of signals using the antennas 1004. For example, in the context of signal transmission, the phases of the transmit signals provided to the antennas 1004 are controlled such that radiated signals from the antennas 1004 combine using constructive and destructive interference to generate an aggregate transmit signal exhibiting beam-like qualities with more signal strength propagating in a given direction. In the context of signal reception, the phases are controlled such that more signal energy is received when the signal is arriving to the antennas 1004 from a particular direction. In certain implementations, the antennas 1004 include one or more arrays of antenna elements to enhance beamforming.

The baseband system 1001 is coupled to the user interface 1007 to facilitate processing of various user input and output (I/O), such as voice and data. The baseband system 1001 provides the transceiver 1002 with digital representations of transmit signals, which the transceiver 1002 processes to generate RF signals for transmission. The baseband system 1001 also processes digital representations of received signals provided by the transceiver 1002. As shown in FIG. 3, the baseband system 1001 is coupled to the memory 1006 of facilitate operation of the mobile device 1000.

The memory 1006 can be used for a wide variety of purposes, such as storing data and/or instructions to facilitate the operation of the mobile device 1000 and/or to provide storage of user information.

The power management system 1005 provides a number of power management functions of the mobile device 1000. The power management system 1005 of FIG. 3 includes an envelope tracker 1060. As shown in FIG. 3, the power management system 1005 receives a battery voltage form the battery 1008. The battery 1008 can be any suitable battery for use in the mobile device 1000, including, for example, a lithium-ion battery.

The mobile device 1000 of FIG. 3 illustrates one example of an RF communication system that can include power amplifier(s) implemented in accordance with one or more features of the present disclosure. However, the teachings herein are applicable to RF communication systems implemented in a wide variety of ways.

FIG. 4 is a schematic diagram of one embodiment of a transmit system for transmitting RF signals from a mobile device. The transmit system 30 includes a battery 1, an envelope tracker 2, a power amplifier 3, a directional coupler 4, a duplexing and switching circuit 5, an antenna 6, a baseband processor 7, a signal delay circuit 8, a digital pre-distortion (DPD) circuit 9, an I/O modulator 10, an observation receiver 11, an intermodulation detection circuit 12, an envelope delay circuit 21, a coordinate rotation digital computation (CORDIC) circuit 22, a shaping circuit 23, a digital-to-analog converter 24, and a reconstruction filter 25.

The transmit system 30 of FIG. 2 illustrates one example of an RF communication system that can include power amplifier(s) implemented in accordance with one or more features of the present disclosure. However, the teachings herein are applicable to RF communication systems implemented in a wide variety of ways.

The baseband processor 7 operates to generate an I signal and a Q signal, which correspond to signal components of a sinusoidal wave or signal of a desired amplitude, frequency, and phase. For example, the I signal can be used to represent an in-phase component of the sinusoidal wave and the Q signal can be used to represent a quadrature-phase component of the sinusoidal wave, which can be an equivalent representation of the sinusoidal wave. In certain implementations, the I and Q signals are provided to the I/O modulator 10 in a digital format. The baseband processor 7 can be any suitable processor configured to process a baseband signal. For instance, the baseband processor 7 can include a digital signal processor, a microprocessor, a programmable core, or any combination thereof.

The signal delay circuit 8 provides adjustable delay to the I and Q signals to aid in controlling relative alignment between the envelope signal and the RF signal RF_{IN}. The amount of delay provided by the signal delay circuit 8 is controlled based on amount of intermodulation detected by the intermodulation detection circuit 12.

The DPD circuit 9 operates to provide digital shaping to the delayed I and Q signals from the signal delay circuit 8 to generate digitally pre-distorted I and Q signals. In the illustrated embodiment, the DPD provided by the DPD circuit 9 is controlled based on amount of intermodulation detected by the intermodulation detection circuit 12. The DPD circuit 9 serves to reduce a distortion of the power amplifier 3 and/or to increase the efficiency of the power amplifier 3.

The I/O modulator 10 receives the digitally pre-distorted I and Q signals, which are processed to generate an RF signal RF_{IN}. For example, the I/O modulator 10 can include DACs configured to convert the digitally pre-distorted I and Q signals into an analog format, mixers for upconverting the analog I and Q signals to radio frequency, and a signal combiner for combining the upconverted I and Q signals into an RF signal suitable for amplification by the power amplifier 3. In certain implementations, the I/O modulator 10 can include one or more filters configured to filter frequency content of signals processed therein.

The envelope delay circuit 21 delays the I and Q signals from the baseband processor 7. Additionally, the CORDIC circuit 22 processes the delayed I and Q signals to generate a digital envelope signal representing an envelope of the RF signal RF_{IN}. Although FIG. 4 illustrates an implementation using the CORDIC circuit 22, an envelope signal can be obtained in other ways.

The shaping circuit 23 operates to shape the digital envelope signal to enhance the performance of the transmit system 30. In certain implementations, the shaping circuit 23 includes a shaping table that maps each level of the digital envelope signal to a corresponding shaped envelope signal level. Envelope shaping can aid in controlling linearity, distortion, and/or efficiency of the power amplifier 3.

In the illustrated embodiment, the shaped envelope signal is a digital signal that is converted by the DAC 24 to an analog envelope signal. Additionally, the analog envelope signal is filtered by the reconstruction filter 25 to generate an envelope signal suitable for use by the envelope tracker 2. In certain implementations, the reconstruction filter 25 includes a low pass filter.

With continuing reference to FIG. 4, the envelope tracker 2 receives the envelope signal from the reconstruction filter 25 and a battery voltage V_{BATT} from the battery 1, and uses the envelope signal to generate a power amplifier supply voltage V_{PA} for the power amplifier 3 that changes in relation to the envelope of the RF signal RF_{IN}. The power amplifier 3 receives the RF signal RF_{IN} from the I/O modulator 10, and provides an amplified RF signal RF_{OUT} to the antenna 6 through the duplexing and switching circuit 5, in this example.

The directional coupler 4 is positioned between the output of the power amplifier 3 and the input of the duplexing and switching circuit 5, thereby allowing a measurement of output power of the power amplifier 3 that does not include insertion loss of the duplexing and switching circuit 5. The sensed output signal from the directional coupler 4 is provided to the observation receiver 11, which can include mixers for down converting I and Q signal components of the sensed output signal, and DACs for generating I and Q observation signals from the downconverted signals.

The intermodulation detection circuit 12 determines an intermodulation product between the I and Q observation signals and the I and Q signals from the baseband processor 7. Additionally, the intermodulation detection circuit 12 controls the DPD provided by the DPD circuit 9 and/or a delay of the signal delay circuit 8 to control relative alignment between the envelope signal and the RF signal RF_{IN}.

By including a feedback path from the output of the power amplifier 3 and baseband, the I and Q signals can be dynamically adjusted to optimize the operation of the transmit system 30. For example, configuring the transmit system 30 in this manner can aid in providing power control, compensating for transmitter impairments, and/or in performing DPD.

Although illustrated as a single stage, the power amplifier 3 can include one or more stages. Furthermore, RF communication systems such as mobile devices can include multiple power amplifiers. In such implementations, separate envelope trackers can be provided for different power amplifiers and/or one or more shared envelope trackers can be used.

Envelope tracking is a technique that can be used to increase power added efficiency (PAE) of a power amplifier by efficiently controlling a voltage level of a power amplifier supply voltage in relation to an envelope of the RF signal amplified by the power amplifier. Thus, when the envelope of the RF signal increases, the voltage supplied to the power amplifier can be increased. Likewise, when the envelope of the RF signal decreases, the voltage supplied to the power amplifier can be decreased to reduce power consumption.

In one example, an envelope tracker includes a DC-to-DC converter that operates in combination with an error amplifier to generate a power amplifier supply voltage based on an envelope signal. For example, the DC-to-DC converter and the error amplifier can be electrically connected in parallel with one another, and the DC-to-DC converter can track low frequency components of the envelope signal while the error amplifier can track high frequency components of the envelope signal. For example, the DC-to-DC converter's switching frequency can be reduced to be less than a maximum frequency component of the envelope signal, and the error amplifier can operate to smooth gaps in the converter's output to generate the power amplifier supply voltage. In certain implementations, the DC-to-DC converter and error amplifier are combined via a combiner.

In another example, an envelope tracker includes a multi-output boost switcher for generating regulated voltages of different voltage levels, a bank of switches for controlling selection of a suitable regulated voltage over time based on the envelope signal, and a filter for filtering the output of the switch bank to generate the power amplifier supply voltage.

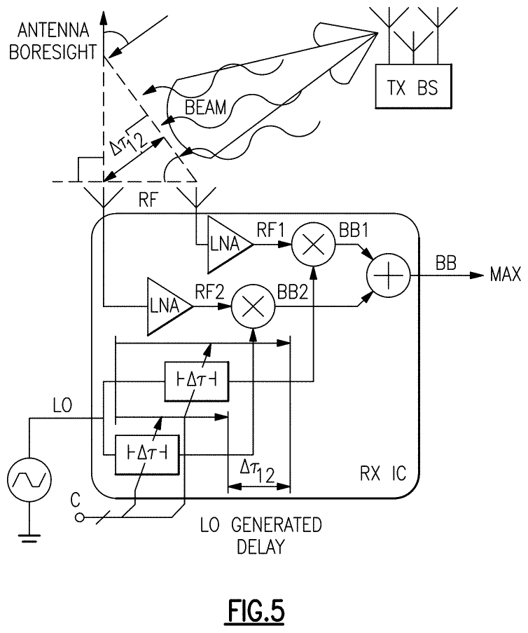

FIG. 5 is an example of structure of two channel receiver front end. It encompasses two RF paths, with LNA and quadrature mixers in each path, baseband summation node (BB) and a delay-based phase-shifting generator (LO) to prototype beam-steering functionality on two-antenna array receiver.

Unlike dividers with phase selectors (DIV+PSELs) or polyphase filters with weighting amplifiers (PPF+VGAs), the design of FIG. 5 provides both tunable phase-shifting and generation of in-phase/quadrature LO components. The design of FIG. 5 may be achieved via passive components, and may include less branched delay lines and combinational logic without dividers, the design of FIG. 5 simplifies the integration of large number of channels with a single LO input and enables future implementations solely with digital place and route tools. One of the ideas of the proposed LO phase-shifting mechanism relies digitally controlled delay lines, where desired beamsteering delay is produced as difference (Δ_{T}12 in FIG. 5) between latencies enabled on individual lines. Individual line latency is constructed with Δ_{T} increments, available from chained delay cells (TD), and demonstrates tunability sufficient for practical low-GHz beamsteering applications.

In information theory, the Shannon-Hartley theorem (Shannon theory) tells the maximum rate at which information can be transmitted over a communications channel of a specified bandwidth in the presence of noise. It is an application of the noisy-channel coding theorem to the archetypal case of a continuous-time analog communications channel subject to Gaussian noise. The theorem establishes Shannon's channel capacity for such a communication link, a bound on the maximum amount of error-free information per time unit that can be transmitted with a specified bandwidth in the presence of the noise interference, assuming that the signal power is bounded, and that the Gaussian noise process is characterized by a known power or power spectral density.

The Shannon theory states the channel capacity C, meaning the theoretical tightest upper bound on the information rate of data that can be communicated at an arbitrarily low error rate using an average received signal power S through an analog communication channel subject to additive white Gaussian noise (AWGN) of power N:

$$C = B {log}_{2} 1 + \frac{S}{N} \qquad [ Equation 1 ]$$

where C is the channel capacity in bits per second, a theoretical upper bound on the net bit rate (information rate, sometimes denoted I) excluding error-correction codes; B is the bandwidth of the channel in hertz (passband bandwidth in case of a bandpass signal); S is the average received signal power over the bandwidth measured in watts (or volts squared); N is the average power of the noise and interference over the bandwidth, measured in watts (or volts squared); and S/N is the signal-to-noise ratio (SNR) or the carrier-to-noise ratio (CNR) of the communication signal to the noise and interference at the receiver (expressed as a linear power ratio, not as logarithmic decibels).

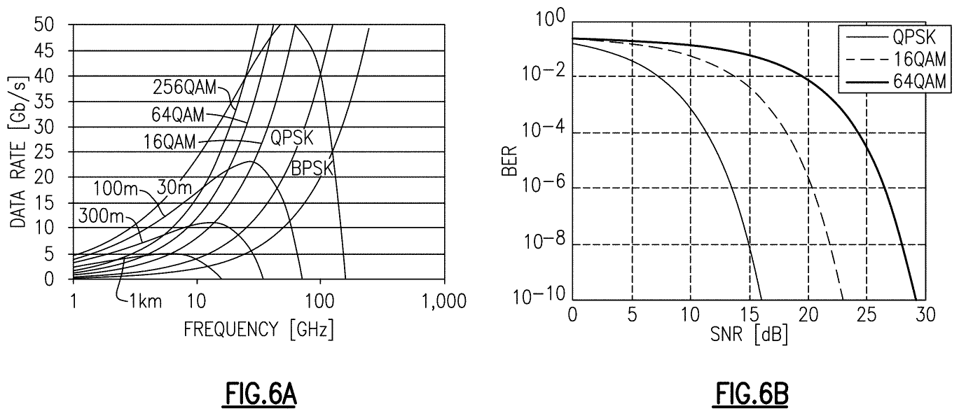

FIGS. 6A and 6B are exemplary graphs describing the data rate and SNR required.

FIG. 6A shows data limit depending on frequency for modulation schemes with different orders of modulation. As shown in FIG. 6A, the modulation schemes with higher order of modulation, which has wider bandwidths, provide larger data rate. However, the higher order of modulation is sensitive and vulnerable to errors, such as noise and fading.

FIG. 6B shows the bit error rate (BER) performance depending on signal-noise ratio (SNR) for modulation schemes with different orders of modulation. As shown in FIG. 6B, bit error rate can be reduced as SNR is bigger. Therefore, according to Shannon theory, it would be beneficial to increase the ratio between the power of carrier signals to the power of noise signal (SNR) in a wave, so that the BER can be enhanced while date rate remains high. In order to increase output power of the power amplifier system, a cascade structure can be used to the power amplifier system.

Gallium arsenide (GaAs) is a wide-spread choice of semiconductor material for high-frequency solid-state devices, components, and integrated circuits (ICs), from amplifiers to switches.

As GaAs devices grew in popularity for RF/microwave applications, they rapidly replaced legacy silicon-based semiconductors, such as bipolar transistors and metal-oxide-semiconductor field-effect transistors (MOSFETs), which were limited in frequency compared to GaAs field-effect transistors (FETs), heterojunction bipolar transistors (HBTs), and high electron mobility transistors (HEMTs).

However, gallium nitride (GaN) has become a further wide-spread high-frequency semiconductor compound, steadily replacing GaAs in many RF/microwave applications, especially where higher-frequency, higher-power semiconductors (high power 5G FEM) are required.

Gallium nitride (GaN) is a very hard, mechanically stable wide bandgap semiconductor. With higher breakdown strength, faster switching speed, higher thermal conductivity and lower on-resistance, power devices based on GaN may significantly outperform silicon-based devices. Gallium nitride crystals can be grown on a variety of substrates, including sapphire, silicon carbide (SiC) and silicon (Si). By growing a GaN epi layer on top of silicon, the existing silicon manufacturing infrastructure can be used eliminating the need for costly specialized production sites and leveraging readily available large diameter silicon wafers at low cost. GaN is used in the production of semiconductor power devices as well as RF components and light-emitting diodes (LEDs). GaN has demonstrated the capability to be the displacement technology for silicon semiconductors in power conversion, RF, and analog applications.

GaN and GaAs are both compound semiconductor materials, each composed of two elements. The materials are grown in the form of ingots, which are cut into thin wafers (see figure) upon which semiconductor devices, including passive circuit elements, are fabricated. GaAs is the more mature material and is commercially available in the form of wafers as large as 6 in diameter while GaN is typically available in wafers.

GaN typically exceeds GaAs in material parameters relating to higher energy and power, and in the speed of achieving higher-energy states. For example, the saturation velocity of GaN, at 2.7×10⁷ cm/s, is somewhat higher than the 2.0×10⁷ cm/s of GaAs. The critical breakdown voltage field determines the highest voltage that can be safely applied to a solid-state device, and the breakdown electric field of GaN, at 4×10⁶ V/cm, is much higher than the 5×10⁵ V/cm of GaAs.

GaN has certain traits that support smaller circuits for a given frequency and power level, allowing the higher power densities and efficiencies much sought after by designers of power-efficient wireless base stations and microcells. For one thing, the higher-voltage capacities of GaN allow the fabrication of much smaller devices for a given power level than on GaAs materials. For example, the defect density of any semiconductor wafer will limit the practical size of circuits that can be manufactured repeatably and reliably on that wafer, implying that device area be minimized for best production yields.

Because the power density of GaN materials is much higher than GaAs or even silicon semiconductor materials, thermal conductivity is an important material parameter for characterizing how well a device will dissipate heat due to dielectric and conductor losses as well as basic device inefficiencies. The thermal conductivity of GaN, at 1.7 W/cm-K, is more than three times the thermal conductivity of GaAs, at 0.46 W/cm-K. High thermal conductivity translates into the lowest temperature rise at conduction, a characteristic that enables GaN devices to handle higher power levels than GaAs devices using the same device structure, such as a field-effect transistor (FET).

The characteristics of GaN FET is described as follows.

Gate Threshold Voltage

The threshold of GaN FETs is lower than that of silicon MOSFETs. This is made possible by the almost flat relationship between threshold and temperature along with the very low gate-to-drain capacitance (Cgd) as described later in this chapter. Since the device starts to conduct significant current at 1.6 V, care must be taken to ensure a low impedance path from gate to source when the device needs to be held off during high speed switching in a rectifier function.

Resistance

Resistance Rds(on) versus Vgs curves are similar to MOSFETs. According to an embodiment, GaN transistors can be designed to operate with 5 V drive. The measured value of Rds(on) flattens as the absolute maximum gate voltage is approached. In this embodiment, as there is negligible gate drive loss penalty, GaN transistors should be driven with 5 V. The temperature coefficient of Rds(on) of the GaN transistor is also similar to the silicon MOSFET.

Capacitance

In addition to the low R, the lateral structure of the GaN FET makes it a very low capacitance device as well. It has the capability of switching hundreds of volts in nanoseconds, giving it multiple megahertz capability. Most important in switching is Cgd. With the lateral structure, Cgd comes only from a small corner of the gate and is much lower than the same capacitance in a vertical MOSFET.

Gate-to-source capacitance (Cgs) consists of the junction from the gate to the channel, and the capacitance of the dielectric between the gate and the field plate. Cgs is large when compared with Cgs, giving GaN FETs good dv/dt immunity, but still small when compared with silicon MOSFETs. This results in very short delay times, and good controllability in low duty cycle applications. The drain-to-source capacitance Cds is also small, being limited to the capacitance across the dielectric from the field plate to the drain. Capacitance versus Voltage curves for GaN FETs are similar to those for silicon except that, for a similar resistance, its capacitance is significantly lower.

Series Gate Resistance and Leakage

Series gate resistance (RG) limits how quickly the capacitance of a field effect transistor can be charged or discharged. Silicon MOSFETs are limited to using polysilicon or silicide where GaN transistors use metal gates. The metal gates enable GaN to have gate resistances of a couple tenths of an ohm. This low gate resistance also helps with dV/dt immunity.

For isolating the gate, oxide growth is not an option with GaN. For this reason, the gate leakage current of GaN transistors is higher than that of silicon MOSFETs. Designers should expect gate leakage in the order of 1 mA. As these are low gate drive voltage devices, losses associated with gate leakage are low.

Body Diode

GaN transistor structure is a purely lateral device, absent of the parasitic bipolar transistor common to silicon based MOSFETs. As such, reverse bias or “diode” operation has a different mechanism but similar function. With zero bias gate to source, there is an absence of electrons under the gate region. As the drain voltage is decreased, a positive bias on the gate is created relative to the drift region, injecting electrons under the gate. Once the gate threshold is reached, there will be sufficient electrons under the gate to form a conductive channel. The benefit to this mechanism is that there are no minority carriers involved in conduction, and therefore no reverse recovery charge (QRR) or loss. While QRR is zero, output capacitance (COSS) has to be charged and discharged with every switching cycle. For devices of similar RDS(on), GaN transistors have significantly lower COSS than silicon MOSFETs. As it takes threshold voltage to turn on the GaN transistor in the reverse direction, the forward voltage of the “diode” is higher than silicon transistors. As with silicon MOSFETs, care should be taken to minimize diode conduction time. As fundamental operation of GaN transistors is similar to that of silicon MOSFETs, they can be represented schematically the same way.

Size

GaN transistors may greatly enhance in Class D audio technology by enabling efficient switching at frequencies above the AM band. Fidelity will approach Class A and Class AB systems without all of the size and weight limitations of linear amplifiers. They will allow high quality amplifiers to be built into very tight spaces such as flat screen televisions, computers and speakers. In information processing and storage systems, the whole power architecture can be re-evaluated to take advantage of the outstanding switching capabilities. As output voltage increases for AC/DC converters, efficiency goes up. As bus voltage increases, transmission efficiency goes up. As frequency increases, size goes down. EPC GaN enables the last stage which enables the first two while increasing AC/DC efficiency when used as synchronous rectifiers. They also allow for intermediate stage converters to be removed for single step conversion, saving the size and cost of the intermediate stage converter.

GaN transistors bring about performance and size advantages over silicon. These advantages can be applied to gain efficiency advantages, size advantages, or a combination of both, with application requirements and a cost structure that are similar to silicon. However, it is required to develop a scheme to linearize the GaN FET to be used in the power amplifier system due to its non-linearity.

Power amplifier systems with increased output power for envelope tracking are described herein.

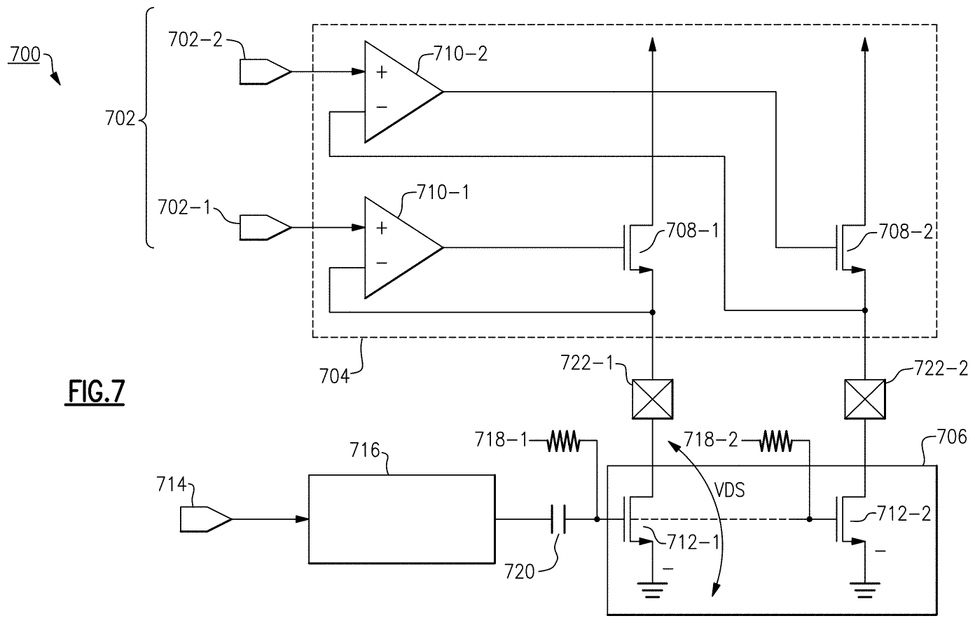

FIG. 7 is an example of structure for power amplifier system according to an embodiment. As shown in FIG. 7, the power amplifier system 700 includes an envelope tracker 702, at least one power amplifier 704, and an adaptation circuit 706.

As described above, the envelope tracker 702 is configured to generate a supply voltage that changes in relation to an envelope of a radio frequency signal. The power amplifier system includes at least one envelope tracker 702-1, 702-2. FIG. 7 illustrates two envelope trackers 702-1, 702-2, but the number of envelope trackers is not limited thereto.

The power amplifier 704 is configured to amplify the radio frequency signal. The radio frequency signal is input through an input node 714. The radio frequency signal is delivered to an input impedance matching circuit 716. The input impedance match circuit 716 is connected to the power amplifier 704 via a capacitor 720 such that the DC signal can be blocked.

The power amplifier 704 includes at least one transistor 712-1, 712-2 that is configured to amplify the radio frequency signal. FIG. 7 illustrates two transistors 712-1, 712-2, but the number of transistors is not limited thereto. The transistors 712-1, 712-2 are complementary metal-oxide semiconductor (CMOS). The transistors 712-1, 712-2 are metal-oxide semiconductor field-effect transistor (MOSFET). Alternatively, the transistors 712-1, 712-2 may be GaN FET. A gate of each transistors 712-1, 712-2 can be connected to a bias node 718-1, 718-2 providing DC bias voltage. A drain of each transistors 712-1, 712-2 is connected to the adaptation circuit 706.

The power amplifier 704 is operated in a linear state that amplifies the radio frequency signal proportionally. The small signal input to the gate of the transistors 712-1, 712-2 is amplified linearly and output to the drain of the transistors 712-1, 712-2. Thus, the radio frequency signal is amplified proportionally to the input small signal. In order to operate the power amplifier 704 in the linear state, proper gate voltages from the bias node 8718-1, 718-2 and drain voltages should be provided to the transistors 712-1, 712-2.

The adaptation circuit 706 is configured to adapt supply voltage generated by the envelope tracker 702. The adaptation circuit 706 is placed between the envelope tracker 702 and the power amplifier 704. The adaptation circuit 706 provides operating power to the power amplifier such that the power amplifier can operate in a linear state.

The adaptation circuit 706 includes at least one GaN FET 708-1, 708-2. The number of GaN FET 708-1, 708-2 corresponds to the number of transistors 712-1, 712-2 of the power amplifier 704. The GaN FET 708-1, 708-2 is configured to generate the operating power in response to an increased swing of the supply voltage. The GaN FET 708-1, 708-2 configure a cascade structure with the transistors 712-1, 712-2, such that the output power of the power amplifier system 700 can be enhanced.

The GaN FET 708-1, 708-2 includes GaN layer positioned on a silicon layer connecting a source and a drain of the GaN FET 708-1, 708-2. The electrical characteristics of GaN FET 708-1, 708-2 are described above. For example, GaN FET 708-1, 708-2 has a lower threshold voltage than a silicon metal-oxide semiconductor field-effect-transistor (MOSFET). The GaN FET 708-1, 708-2 has a lower gate-source capacitance than a silicon MOSFET. In addition, the GaN FET 708-1, 708-2 is non-linear device, and therefore it requires linearization schemes to be properly used in the power amplifier system.

The adaptation circuit 706 includes at least one linearizing circuit 710-1, 710-2. The number of linearization circuit 710-1, 710-2 corresponds to the number of GaN FET 708-1, 708-2. The linearization circuit 706 is configured to compare the operating power provided to the power amplifier 704 with the supply voltage generated by the envelope tracker 702. Particularly, the linearizing circuit 706 is configured to linearize the GaN FET 708-1, 708-2 in response to a voltage swing of the supply voltage. Therefore, the operations of the GaN FET 708-1, 708-2 can be linearized even in high voltage swings, for example 12-15 V.

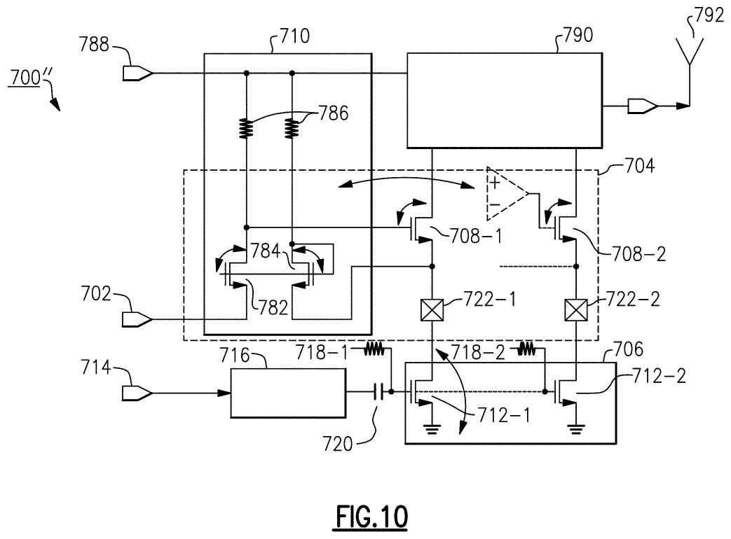

More detailed structure of the adaptation circuit 706 will be described in FIG. 10.

The adaptation circuit 706 is connected to power amplifier 704 via connecting nodes 722-1, 722-2. Each of connecting nodes 722-1, 722-2 may be a copper pilar. The adaptation 706 is placed apart from the power amplifier 704 by a predetermined distance.

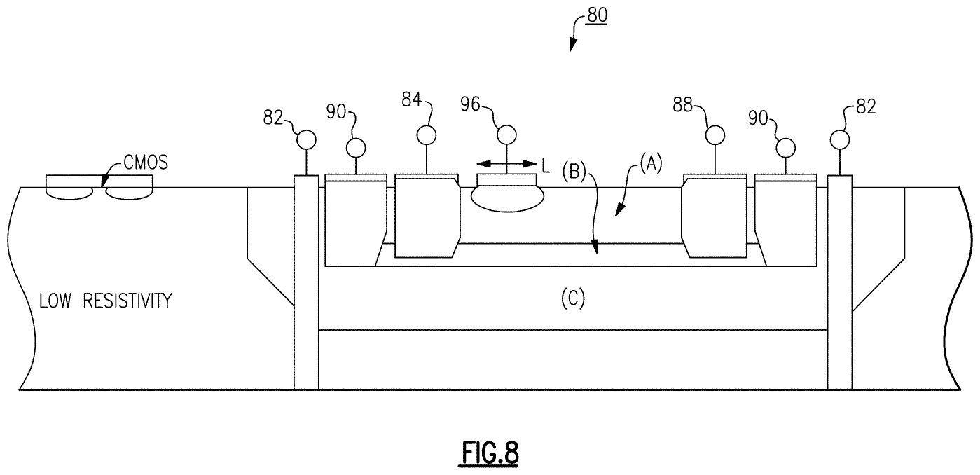

FIG. 8 is an example of structure for GaN FET 80 according to an embodiment.

As shown in FIG. 8, CMOS can be planted with the GaN FET 80 in a single die. The CMOS is a transistor configured to amplify the radio frequency signal in the power amplifier 704. The CMOS is separated from the GaN FET by a through-silicon via (TSV) 82.

The GaN FET 80 includes a source 84, a gate 86 with a width L, and a drain 88. The GaN FET 80 includes a GaN layer (B) positioned on a silicon layer (C). The silicon layer (C) may be deep n-well. The GaN layer (B) connects the source 84 and the drain 88 of the GaN FET 80. The GaN FET 80 includes a AlGaN Shottky barrier layer (A) on the GaN layer (B).

According to an embodiment, the GaN layer (B) can be planted on the silicon layer (C) with 0.13 um, and the GaN FET 80 can be operated in around 9-11V.

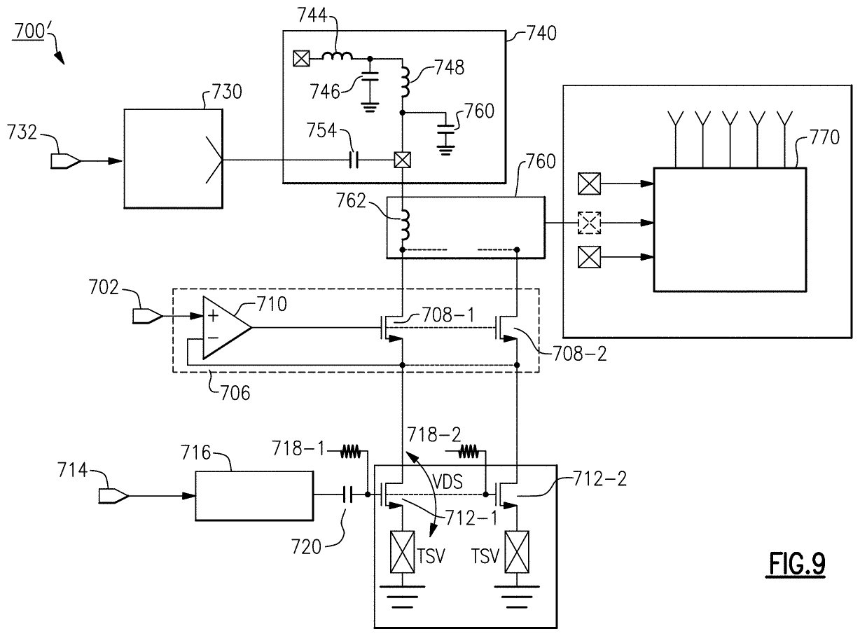

FIG. 9 is an example of structure for power amplifier system 700′ including a multi-level supply (MLS) modulator 730 according to an embodiment. As shown in FIG. 9, the power amplifier system 700′ includes the MLS modulator 730, an ET combiner 740, an output impedance matching circuit 760, and an antenna 770.

The ET MLS is input via an MLS input node 732 to the MLS modulator 730. The MLS modulator 730 is connected to the ET combiner 740.

The ET combiner 740 includes an DC voltage node 742 providing DC voltage. The DC voltage node is connected to a first node via an inductor 744. the first node is connected to a ground via a capacitor 746. The first node is connected to a second node via an inductor 748. The second node is connected to a ground via a capacitor 752. The ET combiner 740 is connected to the ET MLS modulator 730 on the second node via a capacitor 754. The ET combiner 740 is connected to the output impedance matching circuit 760 on the second node of the ET combiner 740.

The output impedance matching circuit 760 is connected to the drain of GaN FET 70-1, 708-2 via a matching inductor 762. The output impedance matching circuit 760 is connected to an antenna 770. The antenna 770 can be placed on a top metal of a device.

The envelope tracker 702, power amplifier 704, and the adjustment circuit 706 shown in FIG. 9 are identical to those of FIG. 7.

FIG. 10 is an example of structure for power amplifier system 700″ according to an embodiment. The power amplifier system 700″ includes an envelope tracker 702, at least one power amplifier 704, an adaptation circuit 706, and an output impedance matching circuit 790 connected to an antenna 792. The adaptation circuit 706 includes a linearizing circuit 710. In FIG. 10, more detailed structure of the linearizing circuit 710 of FIG. 7 is demonstrated. The envelope tracker 702 and the power amplifier 704 shown in FIG. 10 are identical to those of FIG. 7.

As shown in FIG. 10, the linearizing circuit 710 includes a first linearizing transistor 782 and a second linearizing transistor 784. The first linearizing transistor 782 and the second linearizing transistor 784 are GaN FETs.

The first linearizing transistor 782 is configured to receive the supply voltage generated by the envelope tracker 702 and to provide a signal to the GaN FET 708 depending on a signal received from the second linearizing transistor 784. More specifically, the first linearizing transistor 782 has a source connected to the envelope tracker 702, a drain connected to a gate of the GaN FET 708, and a gate connected to a gate of the second linearizing transistor 784. The drain of the first linearizing transistor 784 is connected to a bias node 788 providing a bias voltage. The first linearizing transistor 784 is connected to the bias node 788 via a resistor 786.

The second linearizing transistor 784 is configured to generate a signal to be sent to the first linearizing transistor based on the operating power provided to the power amplifier. More specifically, the second linearizing transistor 784 has a drain connected to a gate of the second linearizing transistor, and a source connected to a source of the GaN FET. The drain of the second linearizing transistor 784 is connected to a bias node 788 providing a bias voltage. The second linearizing transistor 784 is connected to the bias node 788 via a resistor 786.

The linearizing circuit 710 linearizes the GaN FET 708 to operate the power amplifier system 700, 700′, 700″ in a stable state, and the GaN FET 708 enables to output increased power.

Meanwhile, Shannon theory typically assumes isotropic channels. For anisotropic channels, synchronization such in ET and/or polar modulation is necessary.

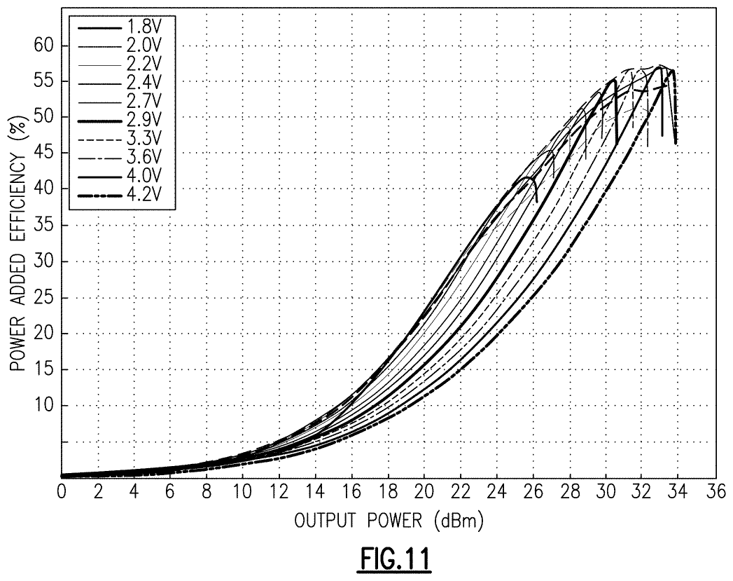

FIG. 11 is an example representing a power added efficiency (PAE) depending on output power for the power amplifier system according to an embodiment. As shown in FIG. 11, increased output power enhances PAE of the power amplifier system. The area with dotted line represents increased power. Each of lines shown in FIG. 11 represents PAE of power amplifier system with synchronization scheme.

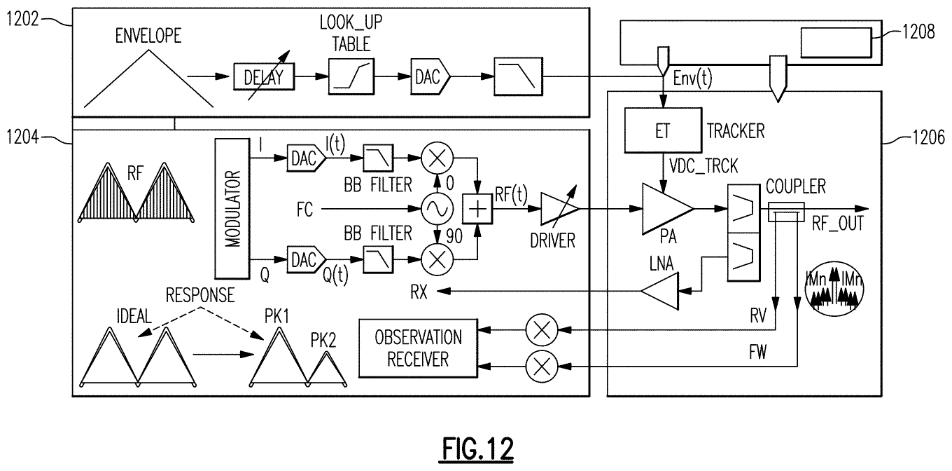

FIG. 12 is an example of structure of communication device for describing synchronization scheme. As shown in FIG. 12, the communication device includes a 4G/5G modem 1202, and a transceiver 1204, a front-end module (FEM) 1206, and a power management integrated circuit 1208.

According to an embodiment, a baseband envelope signal is aligned through a modulated RF signal and the delay is adjusted until the two baseband received signals have the same peak values. The intermodulation distortion introduce by delay mismatch is given by:

IMD_{l,r}=2πB_{RF}²Δ_{τ}² [Equation 2]

where BRF is the bandwidth of the RF signal and Δ_{τ} is the delay mismatch. The minimum between left and right intermodulation distortion determines the ACLR of the ET PA & tracker

ACLR=min(IMD_{l,r})+k [Equation 3]

where k is a correction factor determined by PAPR and how much the PA is operated in compression.

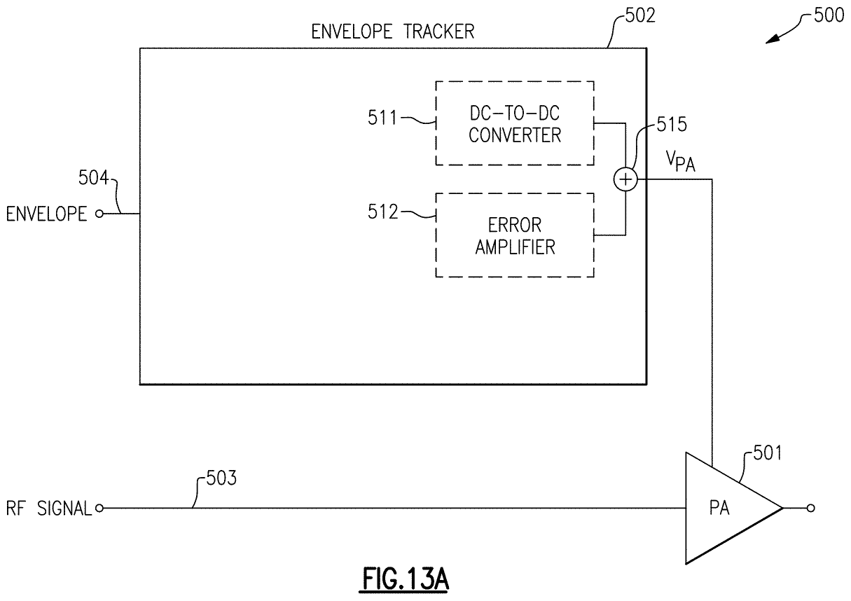

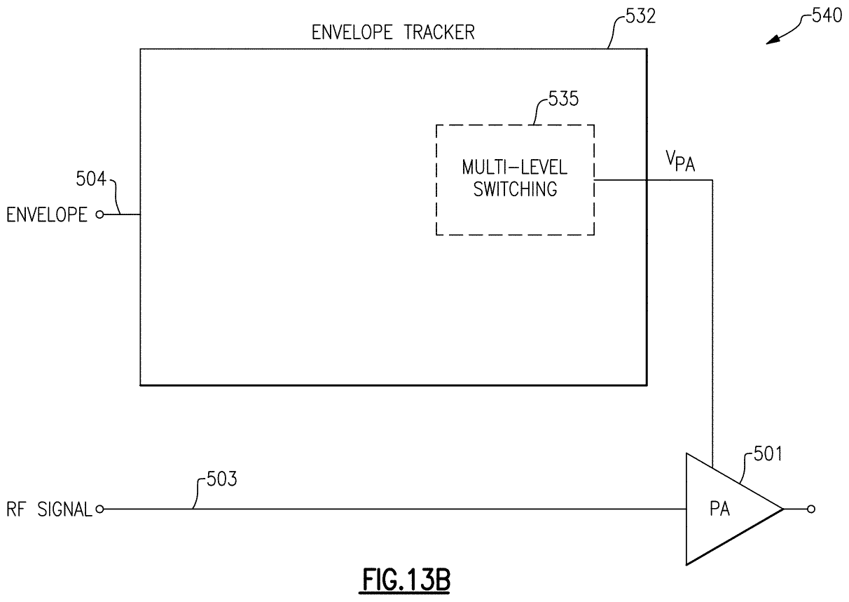

FIG. 13A is a schematic diagram of an envelope tracking system 500 according to one embodiment. The envelope tracking system 500 includes a power amplifier 501 and an envelope tracker 502. The power amplifier 501 provides amplification to a radio frequency signal 503.

The envelope tracker 502 receives an envelope signal 504 corresponding to an envelope of the radio frequency signal 503. Additionally, the envelope tracker 502 generates a power amplifier supply voltage V_{PA}, which supplies power to the power amplifier 501.

The illustrated envelope tracker 502 includes a DC-to-DC converter 511 and an error amplifier 512 that operate in combination with one another to generate the power amplifier supply voltage V_{PA} based on the envelope signal 504. In the illustrated embodiment, an output of the DC-to-DC converter 511 and an output of the error amplifier 512 are combined using a combiner 515.

The envelope tracker 502 of FIG. 13A illustrates one example of analog envelope tracking, in which a switching regulator operate in parallel with one another to track an envelope of an RF signal.

FIG. 13B is a schematic diagram of an envelope tracking system 540 according to another embodiment. The envelope tracking system 540 includes a power amplifier 501 and an envelope tracker 532. The power amplifier 501 provides amplification to a radio frequency signal 503.

The envelope tracker 532 receives an envelope signal 504 corresponding to an envelope of the radio frequency signal 503. Additionally, the envelope tracker 532 generates a power amplifier supply voltage V_{PA}, which supplies power to the power amplifier 501.

The illustrated envelope tracker 532 includes a multi-level switching circuit 535. In certain implementations, the multi-level switching circuit includes a multi-output DC-to-DC converter for generating regulated voltages of different voltage levels, switches for controlling selection of a suitable regulated voltage over time based on the envelope signal, and a filter for filtering the output of the switches to generate the power amplifier supply voltage.

The envelope tracker 532 of FIG. 13B illustrates one example of MLS envelope tracking.

FIG. 14 is a schematic diagram of an envelope tracking system 600 according to another embodiment. The envelope tracking system 600 includes a power amplifier 501 and an envelope tracker 602. The power amplifier 501 provides amplification to a radio frequency signal 503.

The envelope tracker 602 receives an envelope signal corresponding to an envelope of the radio frequency signal 503. In this example, the envelope signal is differential. Additionally, the envelope tracker 602 generates a power amplifier supply voltage V_{PA}, which supplies power to the power amplifier 501.

The illustrated envelope tracker 602 includes an envelope amplifier 611, a first comparator 621, a second comparator 622, a third comparator 623, a coding and dithering circuit 624, a multi-output boost switcher 625, a filter 626, a switch bank 627, and a capacitor bank 630. The capacitor bank 630 includes a first capacitor 631, a second capacitor 632, and a third capacitor 633. Additionally, the switch bank 627 includes a first switch 641, a second switch 642, and a third switch 643.

The envelope amplifier 611 amplifies the envelope signal to provide an amplified envelope signal to the first to third comparators 621-623. The first to third comparators 621-623 compare the amplified envelope signal to a first threshold T1, a second threshold T2, and a third threshold T3, respectively. The results of the comparisons are provided to the coding and dithering circuit 624, which processes the results to control selection of switches of the switch bank 627. The coding and dithering circuit 624 can activate the switches while using coding and/or dithering to reduce artifacts arising from opening and closing the switches.

Although an example with three comparators is shown, more or fewer comparators can be used. Furthermore, the coding and dithering circuit 624 can be omitted in favor of controlling the switch bank in other ways. In a first example, coding but not dithering is used. In a second example, dithering but not coding is used. In a third example, neither coding nor dithering is used.

The multi-output boost switcher 625 generates a first regulated voltage V_{MLS1}, a second regulated voltage V_{MLS2}, and a third regulated voltage V_{MLS3} based on providing DC-to-DC conversion of a battery voltage V_{BATT}. Although an example with three regulated voltages is shown, the multi-output boost switcher 625 can generate more or fewer regulated voltages. In certain implementations, at least a portion of the regulated voltages are boosted relative to the battery voltage V_{BATT}. In some configurations, one or more of the regulated voltages is a buck voltage having a voltage lower than the battery voltage V_{BATT}.

The capacitor bank 630 aids in stabilizing the regulated voltages generated by the multi-output boost switcher 625. For example, the capacitors 631-633 operate as decoupling capacitors.

The filter 626 processes the output of the switch bank 627 to generate the power amplifier supply voltage V_{PA}. By controlling the selection of the switches 641-643 over time based on the envelope signal, the power amplifier supply voltage V_{PA} is generated to track the envelope signal.

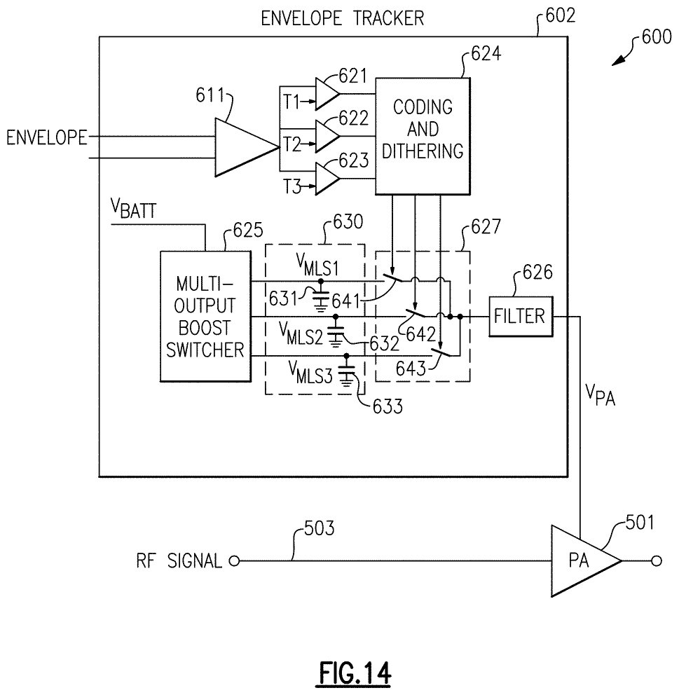

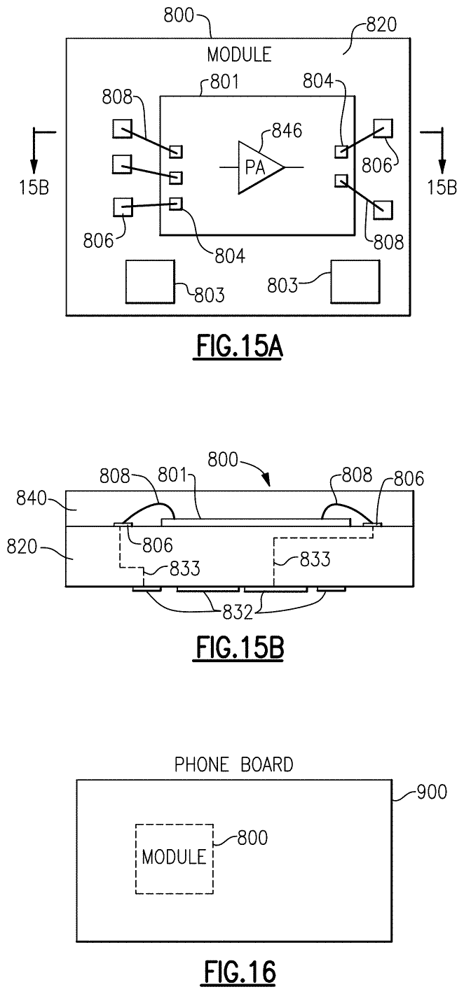

FIG. 15A is a schematic diagram of one embodiment of a packaged module 800. FIG. 15B is a schematic diagram of a cross-section of the packaged module 800 of FIG. 15A taken along the lines 15B-15B.

The packaged module 800 includes an IC or die 801, surface mount components 803, wirebonds 808, a package substrate 820, and encapsulation structure 840. The package substrate 820 includes pads 806 formed from conductors disposed therein. Additionally, the die 801 includes pads 804, and the wirebonds 808 have been used to electrically connect the pads 804 of the die 801 to the pads 806 of the package substrate 801.

The die 801 includes a power amplifier 846, which can be implemented in accordance with any of the embodiments herein.

The packaging substrate 820 can be configured to receive a plurality of components such as the die 801 and the surface mount components 803, which can include, for example, surface mount capacitors and/or inductors.

As shown in FIG. 15B, the packaged module 800 is shown to include a plurality of contact pads 832 disposed on the side of the packaged module 800 opposite the side used to mount the die 801. Configuring the packaged module 800 in this manner can aid in connecting the packaged module 800 to a circuit board such as a phone board of a wireless device. The example contact pads 832 can be configured to provide RF signals, bias signals, power low voltage(s) and/or power high voltage(s) to the die 801 and/or the surface mount components 803. As shown in FIG. 15B, the electrically connections between the contact pads 832 and the die 801 can be facilitated by connections 833 through the package substrate 820. The connections 833 can represent electrical paths formed through the package substrate 820, such as connections associated with vias and conductors of a multilayer laminated package substrate.

In some embodiments, the packaged module 800 can also include one or more packaging structures to, for example, provide protection and/or facilitate handling of the packaged module 800. Such a packaging structure can include overmold or encapsulation structure 840 formed over the packaging substrate 820 and the components and die(s) disposed thereon.

It will be understood that although the packaged module 800 is described in the context of electrical connections based on wirebonds, one or more features of the present disclosure can also be implemented in other packaging configurations, including, for example, flip-chip configurations.

FIG. 16 is a schematic diagram of one embodiment of a phone board 900. The phone board 900 includes the module 800 shown in FIGS. 15A-15B attached thereto. Although not illustrated in FIG. 16 for clarity, the phone board 800 can include additional components and structures.

### Applications

Some of the embodiments described above have provided examples in connection with wireless devices or mobile phones. However, the principles and advantages of the embodiments can be used for any other systems or apparatus that have needs for power amplifiers.

Such envelope trackers can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A power amplifier system comprising:
an envelope tracker configured to generate a supply voltage that changes in relation to an envelope of a radio frequency signal;
a power amplifier configured to amplify the radio frequency signal; and
an adaptation circuit configured to adapt the supply voltage to provide operating power to the power amplifier, the adaptation circuit including at least one Gallium Nitride field-effect-transistor configured to generate the operating power in response to an increased swing of the supply voltage and at least one linearizing circuit configured to linearize an operation of the at least one Gallium Nitride field-effect-transistor, the at least one Gallium Nitride field-effect-transistor having a Gallium Nitride layer positioned on a silicon layer connecting a source and a drain of the at least one Gallium Nitride field-effect-transistor.

2. The power amplifier system of claim 1 wherein the at least one Gallium Nitride field-effect-transistor is configured to provide the power amplifier with the operating power to operate the power amplifier in a linear state that amplifies the radio frequency signal proportionally.

3. The power amplifier system of claim 1 wherein the at least one linearizing circuit is configured to compare the operating power with the supply voltage.

4. The power amplifier system of claim 1 wherein the at least one linearizing circuit includes a first linearizing transistor and a second linearizing transistor.

5. The power amplifier system of claim 4 wherein the first linearizing transistor and the second linearizing transistor are Gallium Nitride field-effect-transistors.

6. The power amplifier system of claim 4 wherein the first linearizing transistor is configured to receive the supply voltage generated by the envelope tracker and to provide a signal to the at least one Gallium Nitride field-effect-transistor depending on a signal received from the second linearizing transistor.

7. The power amplifier system of claim 6 wherein the second linearizing transistor is configured to generate a signal to be sent to the first linearizing transistor based on the operating power provided to the power amplifier.

8. The power amplifier system of claim 6 wherein the first linearizing transistor has a source connected to the envelope tracker, a drain connected to a gate of the at least one Gallium Nitride field-effect-transistor, and a gate connected to a gate of the second linearizing transistor.

9. The power amplifier system of claim 6 wherein the second linearizing transistor has a drain connected to a gate of the second linearizing transistor, and a source connected to a source of the at least one Gallium Nitride field-effect-transistor.

10. A radio frequency module comprising:
a packaging substrate configured to receive a plurality of components; and
a power amplifier system implemented on the packaging substrate, the power amplifier system including an envelope tracker configured to generate a supply voltage that changes in relation to an envelope of a radio frequency signal; a power amplifier configured to amplify the radio frequency signal; and an adaptation circuit configured to adapt the supply voltage to provide operating power to the power amplifier, the adaptation circuit including at least one Gallium Nitride field-effect-transistor configured to generate the operating power in response to an increased swing of the supply voltage and at least one linearizing circuit configured to linearize an operation of the at least one Gallium Nitride field-effect-transistor, the at least one Gallium Nitride field-effect-transistor having a Gallium Nitride layer positioned on a silicon layer connecting a source and a drain of the at least one Gallium Nitride field-effect-transistor.

11. The radio frequency module of claim 10 wherein the radio frequency module is a front-end module.

12. The radio frequency module of claim 10 wherein the at least one Gallium Nitride field-effect-transistor is configured to provide the power amplifier with the operating power to operate the power amplifier in a linear state that amplifies the radio frequency signal proportionally.

13. The radio frequency module of claim 10 wherein the at least one linearizing circuit is configured to compare the operating power with the supply voltage.

14. The radio frequency module of claim 10 wherein the at least one linearizing circuit includes a first linearizing transistor and a second linearizing transistor.

15. The radio frequency module of claim 14 wherein the first linearizing transistor and the second linearizing transistor are Gallium Nitride field-effect-transistors.

16. The radio frequency module of claim 14 wherein the first linearizing transistor is configured to receive the supply voltage generated by the envelope tracker and to provide a signal to the at least one Gallium Nitride field-effect-transistor depending on a signal received from the second linearizing transistor.

17. The radio frequency module of claim 14 wherein the second linearizing transistor is configured to generate a signal to be sent to the first linearizing transistor based on the operating power provided to the power amplifier.

18. The radio frequency module of claim 14 wherein the first linearizing transistor has a source connected to the envelope tracker, a drain connected to a gate of the at least one Gallium Nitride field-effect-transistor, and a gate connected to a gate of the second linearizing transistor.

19. The radio frequency module of claim 14 wherein the second linearizing transistor has a drain connected to a gate of the second linearizing transistor, and a source connected to a source of the Gallium Nitride field-effect-transistor.

20. A mobile device comprising:
a transceiver configured to generate a radio frequency signal;
a power management system including an envelope tracker configured to generate a power amplifier supply voltage that changes is relation to an envelope of the radio frequency signal; and
a front end system including a power amplifier configured to amplify the radio frequency signal; and an adaptation circuit configured to adapt the supply voltage to provide operating power to the power amplifier, the adaptation circuit including at least one Gallium Nitride field-effect-transistor configured to generate the operating power in response to an increased swing of the power amplifier supply voltage and at least one linearizing circuit configured to linearize an operation of the at least one Gallium Nitride field-effect-transistor, the at least one Gallium Nitride field-effect-transistor having a Gallium Nitride layer positioned on a silicon layer connecting a source and a drain of the at least one Gallium Nitride field-effect-transistor.
